(19) United States
(12) Patent Application Publication
(10) Pub. No.: US 2012/0319723 A1
(43) Pub. Date: Dec. 20, 2012

(54) ELECTRIC MACHINE FOR WHICH THE GROUNDING FUNCTION IS MONITORED AND METHOD

(75) Inventors: Jörg Hassel, Erlangen (DE); Carsten Probol, Buckenhof (DE); Arno Steckenborn, Berlin (DE); Oliver Theile, Berlin (DE); Hans Tischmacher, Lauf (DE)

(73) Assignee: Siemens Aktiengesellschaft, Munchen (DE)

(21) Appl. No.: 13/581,582

(22) PCT Filed: Mar. 1, 2010
(86) PCT No.: PCT/EP2010/001258

§ 371 Date: Aug. 28, 2012

(51) Int. Cl. G01R 31/34

(52) U.S. Cl. 324/765.01

(57) ABSTRACT

The grounding quality of an electric machine should be better monitored. Therefore, an electric machine is proposed, comprising a stator (1), a rotor (2), a shaft (3), to which the rotor (2) is fastened, and a grounding device (5) for grounding the shaft. The electric machine also has a measuring device (6) for measuring a ground current of the grounding device (5) and for providing a corresponding measured value. The electric machine also has a monitoring device (7) for monitoring the grounding function of the grounding device (5) on the basis of the measured value. In this way, the state of a grounding brush in regard to soiling and wear, for example, can be continuously monitored.

The present invention relates to an electric machine comprising a stator, a rotor, a shaft to which the rotor is fastened, and a grounding device for grounding the shaft. The present invention furthermore relates to a method for monitoring a grounding function of an electric machine.

Electric machines can have grounding brushes in order for example to keep the armature free of potential (e. g. in the case of wind turbines). Furthermore, electric machines are employed for example in the case of rail vehicles wherein the operating current is conducted away from the rotor by means of grounding brushes. For functional reasons and reasons of protection it is always necessary to monitor the grounding function of the grounding brushes.

Grounding brushes can currently only be monitored for the remaining length becoming too short by means of mechanical systems. In this situation, a contact is opened by means of a microswitch as soon as the brush falls below a minimum length. Monitoring of the grounding capability of grounding brushes is not possible at the present time.

As has already been indicated above, brushes are used in general in the technology sector for transferring electrical energy to moving parts of the overall system. In this situation, a connection is established by means of sliding contacts which are subject to wear. In many applications (e.g. railway drive systems), the motor circuit to the transformer substation is closed by way of the track. Since the track has the function of the return conductor, the entire motor current must be transmitted by way of the wheel bearing away onto the wheel-rail contact. In order to avoid current conduction by way of the roller bearing and a rapid destruction of said assembly the bearing is bridged by a brush-sliding contact. In this case it is important, for a long service life, to monitor the grounding function for brush sparking, functioning of the grounding brush and non-specified high currents in grounding systems.

Grounding brushes are currently not monitored continuously. On account of the limited service life and failures prior to the specified service life, e.g. in the case of electrical and mechanical overloading, grounding brushes are in part implemented redundantly and regularly checked. In this situation, for example, the current supply is taken from the axle shafts by way of special contact brushes and not by way of the bearings of the shafts. Generally speaking, in the case of a four-axle locomotive three axles serve to supply current and the fourth axle is used for grounding the locomotive. The brush of the fourth axle is connected to the chassis of the locomotive. The sum of the currents of the three grounding brushes is compared with the traction current. If the difference between traction current and ground current of the three axles is not equal to zero (fault current), then there must be a defect in the grounding system. The functionality of a fault-current circuit breaker is implemented in this manner, which then trips the main switch of the locomotive in the event of a short-to-ground (short-to-chassis).

With regard to the grounding of electric machines, if remedial maintenance is carried out too late on a defective grounding brush consequential damage may already have been caused to a motor shaft or generator shaft. One example thereof are impermissibly high current transitions in roller bearings (bearing currents). Personal protection and the protection of roller bearings on connected machines (e.g. of a gearbox or a measuring device) can also be affected. Furthermore, unintentional high currents in the grounding system can also lead to problems. Said currents can be produced by magnetic induction, differences in the electrical potential or interference currents in the track in the case of rail vehicles and cause bearing currents or malfunctions as a result of electromagnetic interference.

The object of the present invention consists in providing better monitoring of the grounding function of a grounding device of an electric machine.

This object is achieved according to the invention by an electric machine comprising a stator, a rotor, a shaft to which the rotor is fastened, and a grounding device for grounding the shaft, and also comprising a measuring device for measuring a ground current of the grounding device and for providing a corresponding measured value and also a monitoring device for monitoring a grounding function of the grounding device on the basis of the measured value.

According to the invention, a method is furthermore provided for monitoring a grounding function of an electric machine having a stator, a rotor, a shaft to which the rotor is fastened, and a grounding device for grounding the shaft, by measuring a ground current of the grounding device and providing a corresponding measured value and also monitoring a grounding function of the grounding device on the basis of the measured value.

In an advantageous manner the ground current is therefore registered by an electric machine, the nature and/or size of which ground current allow conclusions regarding the grounding function of the grounding device. With the continuous monitoring of the ground current it is thus possible to ensure a continuous monitoring of the grounding function.

By preference, the ground current can be measured in contactless fashion by means of the measuring device. In particular, a magnetic field or electrical field caused by the ground current can be registered by means of the measuring device. A wear-free measurement process is possible with this contactless measuring method.

Alternatively, the measuring device can have a current probe. Trouble-free measurement independent of external electrical fields and magnetic fields is thus possible.

In a preferred embodiment, the ground current is measured by means of the measuring device in a frequency range from 10 kHz to 10 MHz. In this range, a sufficiently high input coupling usually results and the propagation effects do not yet play a significant role.

The grounding device can moreover have a grounding brush, the ground current of which is determined indirectly by the measuring device through the voltage dropping at said grounding brush. The quality of the grounding brush can be monitored very precisely in this manner. In addition, the measuring device can have a shunt resistance via which the ground current flows, which ground current is measured by the measuring device. Such a measuring resistance is easy to integrate into the system and the voltage drop occurring across it can likewise be easily monitored.

In a preferred application, a rail vehicle is equipped with the aforementioned electric machine and the rail vehicle additionally has a wheel bearing which is bridged electrically by the grounding device, with the result that a ground current of the electric machine flows away as intended by way of the grounding device and not by way of the wheel bearing. Bearing currents can thus be specifically avoided.

In a special embodiment, the rail vehicle has a protective resistance affording protection against high currents, wherein the ground current flows by way of the protective resistance and the measuring device measures or determines the ground current in the protective resistance.

The present invention will now be described in detail with reference to the attached drawings. In the drawings:

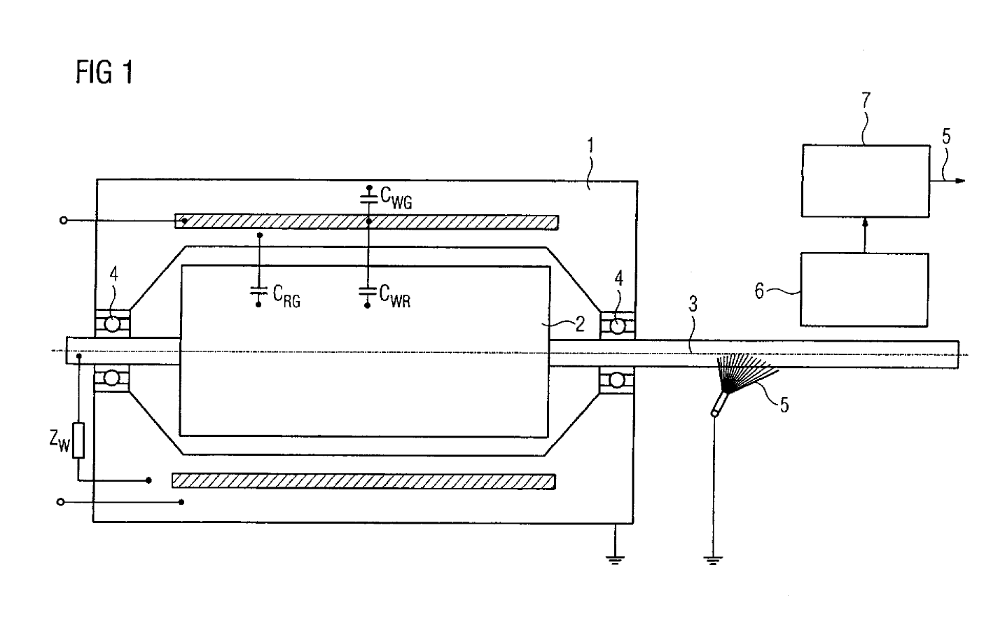

FIG. 1 shows a sketch of an electric machine having a grounding device and monitoring device and

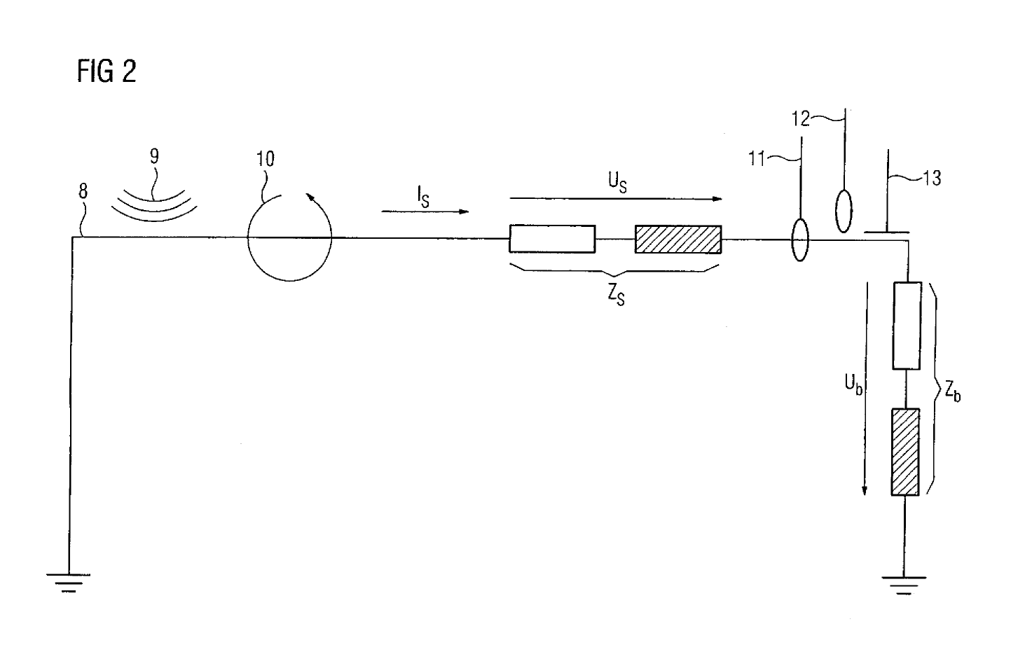

FIG. 2 shows a schematic sketch of monitoring of the grounding function of a grounding device of an electric machine.

The exemplary embodiments described in detail in the following represent preferred embodiments of the present invention.

The example shown in FIG. 1 illustrates an electric machine, here an electric motor, which has a stator 1 and a rotor 2. The rotor 2 is assembled onto a shaft 3. The shaft 3 is mounted on the stator 1 by means of two bearings 4.

In addition, equivalent circuit components for determining the bearing currents are included in the drawing of the electric machine. Firstly, a capacitance C_{WG} is present between the windings of the stator and the chassis. In addition, a capacitance C_{WR} is present between the windings of the stator and the rotor. Furthermore, a capacitance C_{RS} results between the rotor and the chassis. In addition, an impedance Z_{w} can be measured between the shaft 3 and the chassis. A common mode voltage, which is usual during inverter operation, at the windings of the stator is “divided” onto the shaft by way of the capacitive voltage divider (BVR). Bearing voltages are the consequence. If the lubricating film in the bearing is no longer able to hold the voltage, an electric arc is produced which results in bearing currents. It can also be seen from FIG. 1 that the chassis of the electric machine is grounded. In addition, the shaft 3 is also grounded by means of a brush 5. Where appropriate, a motor does not itself have a grounding brush but the electric machine as a whole has a grounding device, e.g. on a wheelset, which is to be monitored.

The grounding function of the brush 5 is monitored here in contactless fashion by means of a measuring device 6 and a monitoring device 7. The monitoring device 7 delivers a corresponding monitoring signal S to the outside which is used either to control the electric machine or to convey a corresponding message to the operator.

In spite of the problem which has already existed for decades associated with being able to adequately monitor the grounding function, no really satisfactory remedy has hitherto been available for this. It has now been recognized by the inventors that the widely held assumption that no voltage drop occurs by way of a grounding brush other than at the sliding contact is incorrect. This means that it is now possible to implement a continuous monitoring of the grounding function.

Implementation of the monitoring of the grounding brush or grounding function can for example be realized by using a measuring system which is capable of detecting AC and DC voltage potentials in contactless fashion. By utilizing, e. g. mounting, this sensor on the fixed bearing shell of the stator of the electric machine, a potential present on the shaft can be recognized prior to the bearing current event. If the brush no longer dissipates the potential, the function of the brush can thus be monitored.

A voltage drop resulting from the ground current can for example be measured at parts of a standard grounding brush 5 or of an additional shunt resistance. The voltage drop is then for example an indication of whether the brush is still long enough or is soiled. Particularly good results can be achieved if a voltage drop is measured at certain frequencies, as is described in detail below.

A further implementation of the monitoring can consist in the fact that a voltage drop is observed across an operational grounding resistance. Such a grounding resistance is for example a protective resistance in a protective grounding system, e. g. 50 mOhm in the case of rail vehicles. If the voltage at this protective resistance falls below a certain threshold value, which must take into consideration the operating state (“are interrupters switched on?”) and can take into consideration frequency ranges or timing characteristics or pulse shapes, then the grounding is faulty.

In one form of implementation, a separate measuring brush can be provided for measuring the ground current. In a further embodiment, a single brush is used both for the grounding and also for the measurement. In this case a changeover switch can be provided in order to switch back and forth between the general operating mode and a measuring mode. In another embodiment of an electric machine, a plurality of grounding brushes is present and one of them is (also) used for the measurement. Independently thereof, a length sensor for monitoring the brush length can also be present for monitoring the grounding function.

The checking of the quality of the grounding function can be important for the wheel bearing. Such a monitoring of the wheel bearings is necessary particularly in the case of rail vehicles. Here the grounding brush bridges the wheel bearing and serves as the return conductor for the traction current by way of the wheel-rail contact. In the event of a defect the resistance of the ground contact increases and an increased passage of current through the wheel bearing itself could result. This would destroy the bearing within a short space of time.

Any current loops inside the electric machine can also lead to undesired effects. Current loops are therefore avoided where possible. By measuring the ground currents it may be possible under certain circumstances to also detect current loops. This additional function regarding the monitoring of the grounding quality may well be advantageous in the case of some applications.

Grounding brushes constitute an impedance for the currents flowing away by way thereof. Said impedance is formed from: the material, the sliding contact, the stranded copper wire which is held in the tamped contact in the brush material, the tamped contact (this may deteriorate during operation as a result of vibration) and the contact between stranded wire and motor chassis. A possible deterioration of the grounding function during actual operation is associated with a deterioration in the sliding contact conditions. Dust, oil, corrosion and other factors can be the reason for the change. A deterioration in the contact conditions is always linked to a change in the current flowing by way of the brush. If said current is measured (e. g. by way of a shunt resistance) and compared with the values pertaining on commissioning of the drive (ideal contact conditions), this allows a statement to be made about the grounding capability of the brush. In addition to the pure measured value in the form of RMS (route mean square) and PK (peak wert) values, histogram classifications of the current can here also be correlated over a defined, extended period of time.

When a measuring system such as a device for monitoring bearing currents is used, e. g. the “bearing current sensor”, which is dependent on the measurements of the pure bearing voltage, it is possible to separate the measurement and grounding functions from one another by means of a switch. At the present time the bearing current sensor can only be used by a non-floating voltage measurement by means of brushes. A brush exclusively for measurement purposes does however have a disadvantageous effect on the volume and costs of an electric machine.

A detailed description now follows in conjunction with FIG. 2 of how the measurement of the ground current can be implemented in principle. To this end, an electrical conductor 8 (e. g. for protective ground) is illustrated which is grounded on both sides. A stray current Iₛ can be induced in the conductor 8 by an electrical field 9 or a magnetic field 10. In particular, through parasitic inductive couplings (in other words by way of the magnetic stray field 10 e.g. of motors or lines against structures which are connected electrically to the protective ground) or parasitic capacitive couplings (in other words by way of the electrical stray field 9 e.g. between the stator winding of motors and the motor chassis or between a conductor of a motor cable and its shield) the protective conductor 8 always carries high-frequency electrical stray currents Iₛ without an insulation error being present. These high-frequency currents result in a voltage drop across a grounding brush, an additional shunt resistance or a protective resistance in the protective ground or the protective conductor 8. The grounding brush is symbolized in FIG. 2 by an impedance Z_{b}. As a rule it has a complex part, e. g. a parasitic inductance. A voltage drop U_{b} can be measured by way thereof.

The ground current can however also, as already mentioned above, be determined with the aid of an additional shunt resistance or a protective resistance which are symbolized in FIG. 2 by the impedance Zₛ. The impedance also has a complex part, e. g. a parasitic inductance. The voltage drop Uₛ is also measured here in order to determine the ground current.

The voltage drop is advantageously measured in a frequency range from 10 kHz to 10 MHz. At still lower frequencies the input coupling is often still slight (exception: inductive input couplings of high currents e.g. at the motor frequency). At higher frequencies a current can flow in the protective resistance as a result of propagation effects although the grounding brush is defective (example: lambda quarter transformer; special case λ/4: at 30 MHz a grounding resistance having a 2.5 m long line would “see” a short-circuit to ground, even if the grounding brush were defective and would constitute an open circuit to ground). A measurement at higher frequencies would however also be possible by means of complex technology/evaluation.

Alternatively, the current in the protective conductor system can also be measured directly by means of a current sensor. This stray current measurement on the protective ground can for example take place using a current probe, which is however extremely complex. The current sensor is identified in FIG. 2 by the reference character 11.

Furthermore, the ground current can also be measured indirectly by way of its effects, namely the electrical field and the magnetic field. To this end, a sensor 12 for the magnetic field and a further sensor 13 for the electrical field are indicated in FIG. 2.

Undesired or even impermissibly high electric currents in current loops, for example as a result of electrical fields, can likewise be measured by means of current measurements or indirect measurements by way of the magnetic field or voltage drop at a shunt resistance.

Damage and dangerous states of the electric machine can be avoided as a result of the continuous monitoring which is thus possible. In addition, maintenance intervals can be extended. For example, with regard to wind turbines a grounding of the generator shaft is necessary in order to avoid high bearing currents in the roller bearings. A malfunction can be detected in this way before the bearing is damaged by ripple formation. This is ultimately achieved in that the measured ground current is evaluated by electronics or logic connected downstream. Where appropriate, corresponding information relating for example to maintenance intervals can then be made available. Optionally, the measured current can also be used directly for controlling the electric machine for example in order to effect a forced shutdown.

### LIST OF REFERENCE CHARACTERS

1 Stator
2 Rotor
3 Shaft
4 Bearing
5 Brush
6 Measuring device
7 Monitoring device
8 Conductor
9 Electrical field
10 Magnetic field
11 Current sensor
12 Sensor
13 Sensor
C_{WG} Capacitance
C_{WR} Capacitance
C_{RC} Capacitance
S Monitoring signal
Z_{b}, Z_{W}, Z_{S} Impedance
U_{b}, U_{S} Voltage drop

1-10. (canceled)

11. An electric machine, comprising:
a stator,
a rotor,
a shaft to which the rotor is fastened,
a grounding device for grounding the shaft,
a measuring device for measuring a ground current in a frequency range from 10 kHz to 10 MHz and for providing a corresponding measured ground current value, and
a monitoring device for monitoring a grounding function of the grounding device based on the measured ground current value.

12. The electric machine of claim 11, wherein the ground current is measured contactless.

13. The electric machine of claim 2, wherein the measuring device measures a magnetic field or an electric field caused by the ground current.

14. The electric machine of claim 11, wherein the measuring device comprises a current probe.

15. The electric machine of claim 11, wherein the grounding device comprises a grounding brush and the ground current flows through the grounding brush.

16. A rail vehicle comprising
a wheel bearing, and
an electric machine with
a stator,
a rotor,
a shaft to which the rotor is fastened, said shaft supported in the wheel bearing,
a grounding device electrically bridging the wheel bearing,
a measuring device for measuring a ground current in a frequency range from 10 kHz to 10 MHz and for providing a corresponding measured ground current value, and
a monitoring device for monitoring a grounding function of the grounding device based on the measured ground current value,
wherein the ground current of the electric machine flows through the grounding device and bypasses the wheel bearing.

17. The rail vehicle of claim 16, comprising a shunt resistance or a protective resistor protecting against high currents, wherein the measuring device measures the ground current flowing through the protective resistor.

18. A method for monitoring a grounding function of an electric machine which comprises a stator, a rotor, a shaft to which the rotor is attached, and a grounding device for grounding the shaft, the method comprising the steps of:
measuring a ground current of the grounding device based on a voltage drop produced by the ground current across the grounding brush, an additional shunt resistance or a protective resistance in a frequency range from 10 kHz to 10 MHz,
providing a measurement value based on the measured ground current, and
monitoring a grounding function of the grounding device based on the measurement value.
